(19) United States
(12) Patent Application Publication
(10) Pub. No.: US 2024/0426903 A1
(43) Pub. Date: Dec. 26, 2024

(54) ELECTRICAL CONNECTION APPARATUS

(71) Applicant: Kabushiki Kaisha Nihon Micronics, Tokyo (JP)

(72) Inventors: Souichi KANOSUE, Oita (JP); Masataka KIMOTO, Oita (JP); Toshihisa KADOWAKI, Oita (JP); Shin SAKIYAMA, Oita (JP)

(21) Appl. No.: 18/747,199

(22) Filed: Jun. 18, 2024

(30) Foreign Application Priority Data
Jun. 21, 2023 (JP) 2023-102027

(51) Int. Cl. G01R 31/28; G01R 1/04

(52) U.S. Cl. CPC G01R 31/2884; G01R 1/0466; G01R 31/2889; G01R 31/2896

(57) ABSTRACT

An electrical connection apparatus includes probes, a wiring board, a wiring sheet, and a printed board. The wiring board includes first electrodes each of which is connected to any one of the probes, and second electrodes each of which is electrically connected to any one of the first electrodes. The wiring sheet includes a first connection portion arranged on a first main surface, a second connection portion arranged on a second main surface facing the first main surface, and an internal circuit electrically connected to the first connection portion, and is laminated on the wiring board such that the first connection portion is connected to the second electrodes. The printed board faces the wiring board with the wiring sheet therebetween, and includes wiring patterns connected to the second connection portion. The wiring sheet is configured in an attachable/detachable manner between the wiring board and the printed board.

### CROSS-REFERENCE TO RELATED APPLICATIONS

The present application is based on and claims the benefit of priority from the prior Japanese Patent Application No. 2023-102027, filed on Jun. 21, 2023, the entire contents of which are incorporated by reference herein.

### TECHNICAL FIELD

The present invention relates to an electrical connection apparatus used for inspecting electrical characteristics of an object to be inspected.

### BACKGROUND

To measure electrical characteristics of an object to be inspected such as an integrated circuit, an electrical connection apparatus having a terminal for inspection in contact with the object to be inspected is used. In the measurement using the electrical connection apparatus, the object to be inspected is electrically connected to an inspection device such as a tester via the terminal for inspection.

In order to measure various characteristics of the object to be inspected, the electrical connection apparatus is required to have various configurations depending on the measurement. An electrical connection apparatus including a circuit for electrically connecting the object to be inspected and the inspection device is used for inspection performed by propagating an electrical signal between the object to be inspected and the inspection device, for example. In addition, an electrical connection apparatus including a circuit for electrically connecting an output terminal and an input terminal of the object to be inspected is used for inspection performed by inputting a signal output from the output terminal of the object to be inspected to the input terminal of the object to be inspected. In order to perform these measurements, a configuration has been investigated in which a relay element for performing switching of circuits is arranged in an electrical connection apparatus.

### BRIEF SUMMARY

By ensuring high quality with the reduced loss of an electrical signal propagating through an electrical connection apparatus and reduced noise, characteristics of an object to be inspected can be measured with high accuracy. An object of the present invention is to provide an electrical connection apparatus capable of measuring characteristics of an object to be inspected with high accuracy.

An electrical connection apparatus according to an aspect of the present invention includes terminals for inspection, a wiring board, a wiring sheet, and a printed board. The wiring board includes first electrodes each of which is connected to any one of the plurality of terminals for inspection, and second electrodes each of which is electrically connected to any one of the first electrodes. The wiring sheet includes a first connection portion arranged on a first main surface, a second connection portion arranged on a second main surface facing the first main surface, and an internal circuit electrically connected to the first connection portion, and is laminated on the wiring board such that the first connection portion is connected to the second electrodes. The printed board faces the wiring board with the wiring sheet therebetween, and includes wiring patterns connected to the second connection portion. The wiring sheet is configured in an attachable/detachable manner between the wiring board and the printed board.

### BRIEF DESCRIPTION OF THE DRAWINGS

FIG. 1 is a schematic view showing a configuration of an electrical connection apparatus according to an embodiment.

FIG. 2A is a schematic plan view showing the configuration of the electrical connection apparatus according to an embodiment.

FIG. 2B is a schematic cross-sectional view showing the configuration of the electrical connection apparatus according to an embodiment.

FIG. 3 is a schematic cross-sectional view showing an example of a configuration of a wiring sheet of the electrical connection apparatus according to an embodiment.

FIG. 4 is a schematic view showing an example of an internal circuit of the wiring sheet of the electrical connection apparatus according to an embodiment.

FIG. 5 is a schematic view showing another example of an internal circuit of the wiring sheet of the electrical connection apparatus according to an embodiment.

FIG. 6 is a schematic view showing another example of an internal circuit of the wiring sheet of the electrical connection apparatus according to an embodiment.

FIG. 7 is a schematic view showing an example of a loopback circuit using the wiring sheet shown in FIG. 6.

FIG. 8 is a schematic view showing another example of an internal circuit of the wiring sheet of the electrical connection apparatus according to an embodiment.

FIG. 9 is a schematic view showing another example of an internal circuit of the wiring sheet of the electrical connection apparatus according to an embodiment.

FIG. 10 is a schematic view showing an example of an internal circuit of a wiring sheet of an electrical connection apparatus according to another embodiment.

### DETAILED DESCRIPTION

Embodiments of the present invention will be described with reference to the drawings. In the description of the drawings below, the same or similar parts are denoted with the same or similar reference numerals. However, it should be noted that the drawings are schematically shown and the ratios of the thickness of each portion and the like are different from those in reality. Further, it is needless to say that the drawings include portions where the relationships and ratios of dimensions are different between drawings. The following embodiments exemplify an apparatus and a method for embodying the technical concept of the present invention, and the embodiments of the present invention do not specify the material, shape, structure, arrangement, and the like of components to the following.

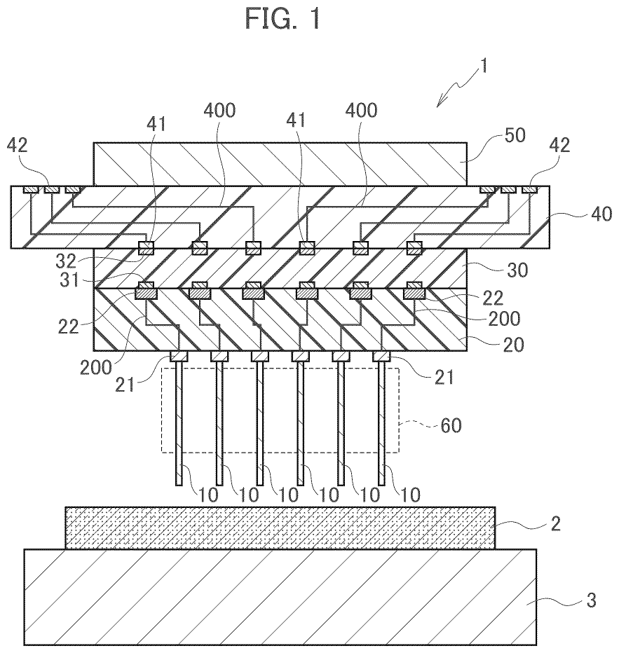

An electrical connection apparatus 1 according to an embodiment shown in FIG. 1 is used for inspecting an object 2 to be inspected. The electrical connection apparatus 1 includes a plurality of probes 10 that come into contact with the object 2 to be inspected when the object 2 to be inspected is inspected, a wiring board 20 connected to the probes 10, a wiring sheet 30 laminated on the wiring board 20, and a printed board 40 laminated on the wiring sheet 30. The plurality of probes 10 function as a plurality of terminals for inspection for electrically connecting the object 2 to be inspected and an inspection device. The electrical connection apparatus 1 shown in FIG. 1 further includes a stiffener 50 laminated on the printed board 40. In the following description, a direction in which the electrical connection apparatus 1 is located when viewed from the object 2 to be inspected is defined as an upward direction, and a direction in which the object 2 to be inspected is located when viewed from the electrical connection apparatus 1 is defined as a downward direction. Further, a surface facing the upward direction of each component of the electrical connection apparatus 1 will be referred to as an upper surface, and a surface facing the downward direction will be referred to as a lower surface.

The object 2 to be inspected is mounted on a stage 3. The electrical connection apparatus 1 and the stage 3 are relatively movable in an up-down direction. When the object 2 to be inspected is inspected, a distance between the electrical connection apparatus 1 and the stage 3 is made small, and one end (hereinafter also referred to as a “tip”) of each of the probes 10 contacts a signal terminal (not shown) of the object 2 to be inspected. FIG. 1 shows a state in which the probes 10 and the object 2 to be inspected are separated. The probes 10 may be supported by a probe head 60 through which the probes 10 pass. The probe head 60 may be a housing having an internal space. The probe head 60 is fixed to the wiring board 20, for example. The other end (hereinafter also referred to as a “proximal end”) of each of the probes 10 connected to a tip is connected to the wiring board 20.

The wiring board 20 includes a plurality of first electrodes 21 each of which is electrically connected to a proximal end of any one of the plurality of probes 10, and a plurality of second electrodes 22 each of which is electrically connected to any one of the first electrodes 21. The second electrodes 22 are electrically connected to the first electrodes 21 via connecting wiring 200. The connecting wiring 200 may be internal wiring arranged inside the wiring board 20, for example. A multilayer wiring board such as a Multi-Layer Organic (MLO) board or a Multi-Layer Ceramic (MLC) board may be used for the wiring board 20, for example.

The wiring sheet 30 has first connection portions 31 arranged on a first main surface thereof and second connection portions 32 arranged on a second main surface facing the first main surface. The first main surface of the wiring sheet 30 serves as a lower surface of the wiring sheet 30 facing the wiring board 20. The second main surface of the wiring sheet 30 serves as an upper surface of the wiring sheet 30 facing the printed board 40. The wiring sheet 30 is laminated on the wiring board 20 such that the first connection portions 31 are connected to the second electrodes 22 of the wiring board 20. The wiring sheet 30 includes an internal circuit electrically connected to the first connection portions 31 at an interior portion between the first main surface and the second main surface. FIG. 1 does not show the internal circuit.

The printed board 40 faces the wiring board 20 with the wiring sheet 30 therebetween. The printed board 40 includes wiring patterns 400 for electrically connecting the second connection portions 32 of the wiring sheet 30 and an inspection device. First ends 41 of the wiring patterns 400 disposed inside and on a surface of the printed board 40 are connected to the second connection portions 32 of the wiring sheet 30, and second ends 42 of the wiring patterns 400 are electrically connected to the inspection device (not shown), for example. The first ends 41 are disposed on a lower surface of the printed board 40, and the second ends 42 are disposed on an upper surface of the printed board 40.

The wiring sheet 30 may be selected from among a plurality of wiring sheet candidates included in a wiring sheet group which will be described later in detail. Each of the wiring sheet candidates has a first connection portion 31 disposed on the first main surface, a second connection portions 32 disposed on the second main surface, and an internal circuit electrically connected to the first connection portion 31. Each of the wiring sheet candidates included in the wiring sheet group may include an internal circuit having a configuration different from that of another wiring sheet candidates therein. One wiring sheet 30 selected from among the plurality of wiring sheet candidates included in the wiring sheet group is laminated on the wiring board 20 such that the first connection portions 31 are connected to the second electrodes 22 of the wiring board 20.

The wiring sheet 30 is configured in an attachable/detachable manner between the wiring board 20 and the printed board 40 of the electrical connection apparatus 1. In order to replace the wiring sheet 30 laminated on the wiring board 20 with another wiring sheet candidate, the wiring sheet 30 is attached and detached between the wiring board 20 and the printed board 40, for example.

The wiring board 20 may be a space transformer that extends a distance between the proximal ends of the probes 10 to a distance between the first ends 41 of the printed board 40 when viewed from a direction normal to a main surface of the wiring board 20, for example. By using the space transformer for the wiring board 20, it is possible to electrically connect the proximal ends of the probes 10 corresponding to a distance between signal terminals arranged on the object 2 to be inspected, to the wiring patterns 400 in the printed board 40 arranged at a distance larger than a distance between the proximal ends. This facilitates the electrical connection between the wiring patterns 400 in the printed board 40 and the inspection device.

As shown in FIG. 1, the stiffener 50 may be laminated on the printed board 40. The stiffener 50 has higher stiffness than the printed board 40, and ensures the mechanical strength of the electrical connection apparatus 1 by preventing the printed board 40 from being bent. In addition, the stiffener 50 may be used as a support for fixing each component of the electrical connection apparatus 1. The stiffener 50 may be fixed to the printed board 40 using screws, for example.

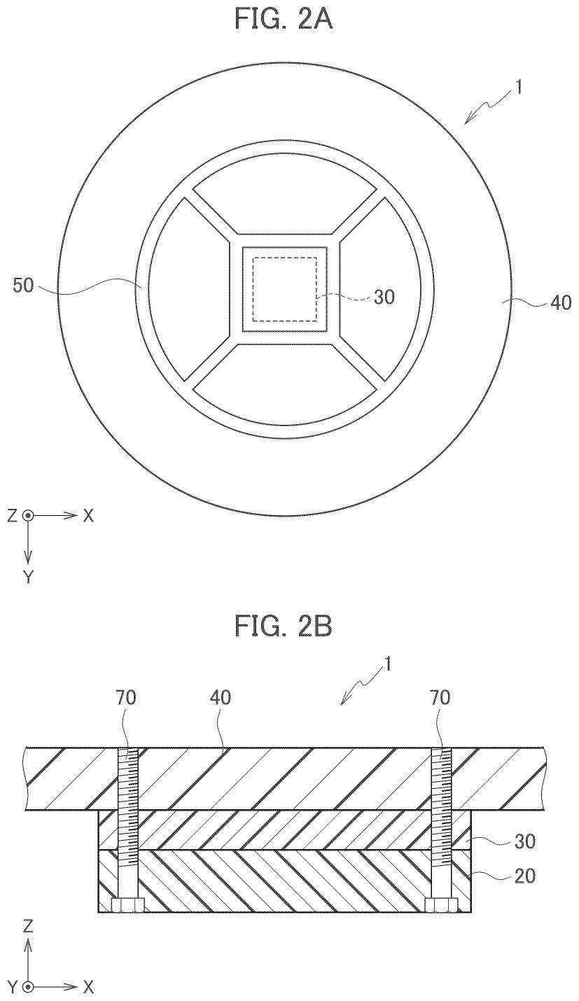

FIG. 2A is a plan view (hereinafter also referred to as “in plan view”) of a structure in which the wiring board 20, the wiring sheet 30, the printed board 40, and the stiffener 50 are laminated, as viewed from a Z direction. In FIG. 2A, the Z direction is a front-back direction of the page space, an X direction is a left-right direction of the page space, and a Y direction is an up-down direction of the page space. FIG. 2B is a cross-sectional view of a side surface as viewed from the Y direction of an XY plane perpendicular to the Z direction.

The stiffener 50 is arranged on an upper surface of the printed board 40 that is circular in plan view. As shown in FIG. 2A, the stiffener 50 has a shape in which an outer circular ring and an inner rectangular ring are connected using spokes, for example. The wiring board 20 and the wiring sheet 30 are arranged in the vicinity of the center of a lower surface of the printed board 40. The wiring board 20, the wiring sheet 30, the printed board 40, and the stiffener 50 are fixed with screws, for example. FIG. 2B shows an example in which the wiring board 20, the wiring sheet 30, and the printed board 40 are joined using screws 70.

The wiring sheet 30 of the electrical connection apparatus 1 is configured in an attachable/detachable manner between the wiring board 20 and the printed board 40 in order to replace the wiring sheet 30 with another wiring sheet candidates included in the wiring sheet group. The wiring board 20 is detached from the wiring sheet 30, and then the wiring sheet 30 is detached from the printed board 40, for example. A new wiring sheet 30 selected from the wiring sheet candidates is attached to the printed board 40. Thereafter, the wiring board 20 is attached to the wiring sheet 30.

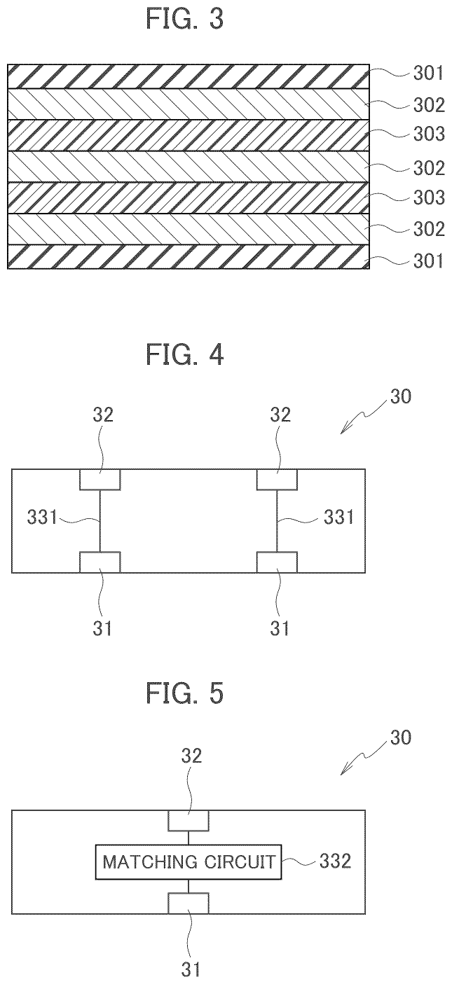

The wiring sheet 30 may have a structure in which a conductive film and an insulating film are laminated. An internal circuit may be constituted from a conductive pattern formed on a conductive film, for example. FIG. 3 shows an example of a configuration of the wiring sheet 30. The wiring sheet 30 shown in FIG. 3 has a structure in which laminated bodies of conductive films 302 and insulating films 303 are interposed between a pair of cover films 301 of insulating materials. The number of laminated bodies of the conductive films 302 and the insulating films 303 can be set to any number. The conductive films 302 may be metal materials such as copper foil, for example. The insulating films 303 may be insulating materials such as polyimide sheets, for example. The cover films 301 may be insulating materials such as solder resists, for example. An adhesive may be used for joining the conductive films 302, the insulating films 303, and the cover films 301 each other, for example. The wiring sheet 30 may have a structure in which a film (also referred to as a “base film”) of an insulating material is further interposed between the laminated bodies including the conductive films 302 and the insulating films 303.

An example of the configuration of the wiring sheet candidates included in the wiring sheet group will be described below. In the following, when each of the wiring sheet candidates is not limited, the wiring sheet candidates will be collectively referred to as a wiring sheet 30.

An internal circuit of a wiring sheet 30 as any one of the group of wiring sheets may include a circuit (hereinafter also referred to as an “interposer circuit”) for electrically connecting the first connection portions 31 and the second connection portions 32. When an interposer circuit is formed on the wiring sheet 30 of the structure shown in FIG. 3, wiring is formed, which passes through the cover films 301, the conductive films 302, and the insulating films 303, from the first main surface to the second main surface of the wiring sheet 30, for example.

If the internal circuit of the wiring sheet 30 includes the interposer circuit, the internal circuit of the wiring sheet 30 shown in FIG. 4 may include a circuit for short-circuiting the first connection portions 31 and the second connection portions 32. In the internal circuit of the wiring sheet 30 shown in FIG. 4, the first connection portions 31 and the second connection portions 32 are electrically short-circuited by short-circuit wiring 331.

By attaching the wiring sheet 30 shown in FIG. 4 to the electrical connection apparatus 1, the probes 10 and the wiring patterns 400 in the printed board 40 are short-circuited via the internal circuit of the wiring sheet 30. This electrically connects the object 2 to be inspected and the inspection device. As a result, an electrical signal propagates between an inspection device such as an IC tester and the object 2 to be inspected to measure characteristics of the object 2 to be inspected. A first connection portion 31 of the first connection portions 31 and a second connection portion 32 of the second connection portions 32 are connected in a one-to-one relationship by means of the internal circuit of the wiring sheet 30, for example. Alternatively, one first connection portion 31 may be connected to a plurality of second connection portions 32 or a plurality of first connection portions 31 may be connected to one second connection portion 32 by means of the internal circuit.

When the internal circuit of the wiring sheet 30 includes the interposer circuit, the internal circuit may include a matching circuit 332 having a first terminal connected to the first connection portion 31 and a second terminal connected to the second connection portion 32, as shown in FIG. 5. The matching circuit 332 may perform impedance matching between the first connection portion 31 and the second connection portion 32. The matching circuit 332 may include a 7r-type filter, for example.

The internal circuit of the wiring sheet 30 may include a circuit for electrically connecting any one of the first connection portions 31 and the other one of the first connection portions 31. In other words, the internal circuit of the wiring sheet 30 may include a circuit for electrically connecting an output terminal and an input terminal of the object to be inspected 2 (hereinafter also referred to as a “loopback circuit”). Two signal terminals of the object to be inspected 2 are electrically connected by the loopback circuit.

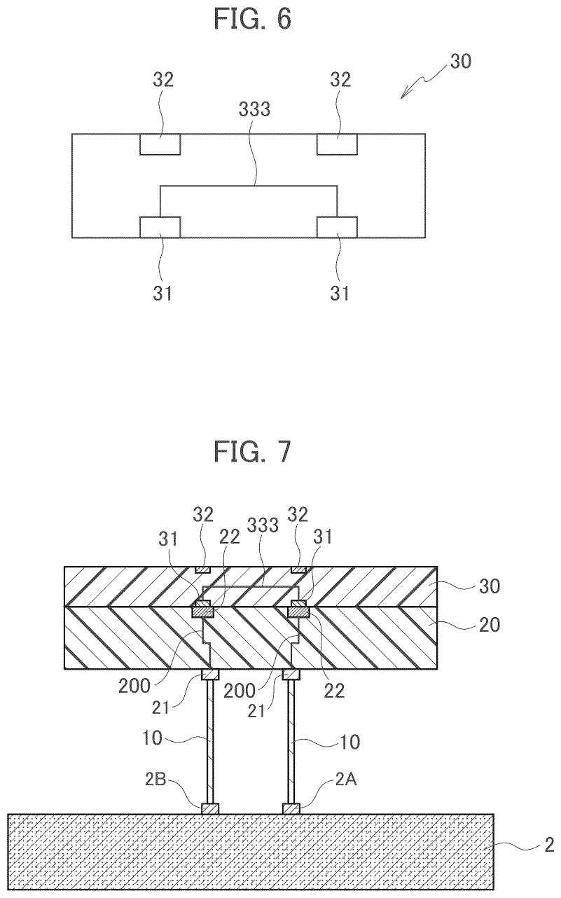

The internal circuit of the wiring sheet 30 may include a circuit for short-circuiting any one of the first connection portions 31 and the other one of the first connection portions 31, as shown in FIG. 6, for example. In the internal circuit of the wiring sheet 30 shown in FIG. 6, one first connection portion 31 and the other first connection portion 31 are electrically short-circuited by loopback wiring 333. By attaching the wiring sheet 30 shown in FIG. 6 to the electrical connection apparatus 1, one of the probes 10 and the other one of the probes 10 are short-circuited via the internal circuit of the wiring sheet 30. This electrically connects one signal terminal and the other signal terminal of the object 2 to be inspected.

FIG. 7 shows a configuration in which a first signal terminal 2A of the object 2 to be inspected in contact with one of the probes 10, and a second signal terminal 2B of the object 2 to be inspected in contact with the other one of the probes 10 are electrically connected via the loopback wiring 333 of the wiring sheet 30. Suppose that the object 2 to be inspected is a receiving circuit, the first signal terminal 2A is an output terminal of the object 2 to be inspected, and the second signal terminal 2B is an input terminal of the object 2 to be inspected, for example. In the above case, a transmission test can be performed by returning an output from the object 2 to be inspected to an input. In other words, it is possible to test whether an output unit and an input unit of the object 2 to be inspected are functioning normally, even if there is no destination equipment for transmission. As an inspection in accordance with a jitter tolerance test performed for a receiving circuit, an output signal output from the first signal terminal 2A (output terminal) may be input to the second signal terminal 2B (input terminal) as an input signal to inspect whether a specified error rate is ensured, for example.

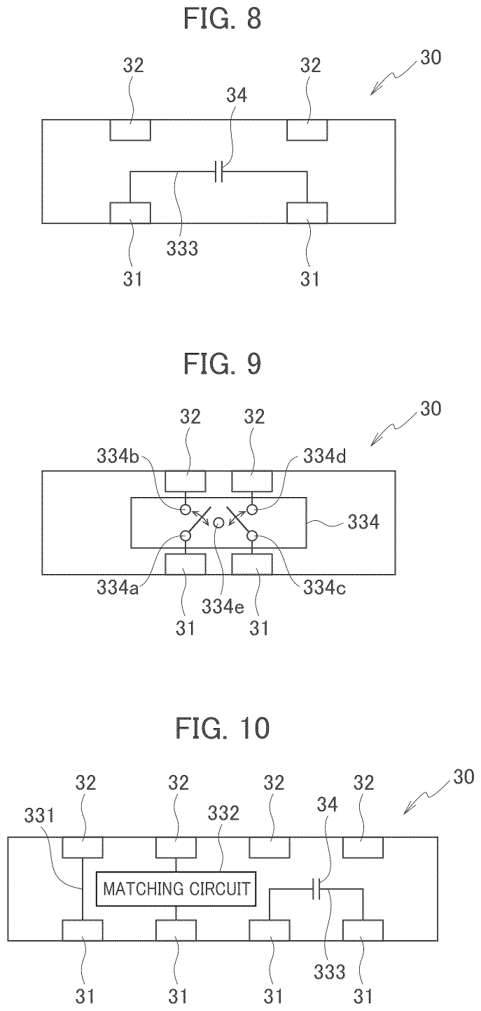

If the internal circuit of the wiring sheet 30 includes the loopback circuit, the internal circuit may include a circuit having a capacitor 34 connected in series between any one of the first connection portions 31 and the other one of the first connection portions 31, as shown in FIG. 8. One terminal of the capacitor 34 is connected to any one of the first connection portions 31, and the other terminal of the capacitor 34 is connected to the other one of the first connection portions 31. The capacitor 34 may be a capacitor (hereinafter also referred to as a “process capacitor”) formed using a semiconductor manufacturing process.

Further, the internal circuit of the wiring sheet 30 may include a relay circuit that switches to electrically connect one of the first connection portions 31 to either one of the second connection portions 32 or the other one of the first connection portions 31. The internal circuit shown in FIG. 9 includes a relay circuit 334 that constitutes either one of an interposer circuit for connecting the first connection portions 31 and the second connection portions 32 and a loopback circuit for connecting the first connection portions 31 each other, for example.

If the relay circuit 334 shown in FIG. 9 constitutes an interposer circuit, a first contact terminal 334a and a second contact terminal 334b are connected, and a third contact terminal 334c and a fourth contact terminal 334d are connected. This electrically connects the first connection portions 31 and the second connection portions 32. If the relay circuit 334 constitutes a loopback circuit, the first contact terminal 334a and a common contact terminal 334e of the relay circuit 334 are connected, and the third contact terminal 334c and the common contact terminal 334e are connected. This electrically connects one of the first connection portions 31 and the other one of the first connection portions 31.

Although examples of the internal circuit of the wiring sheet 30 have been described with reference to FIGS. 4 to 9, it is needless to say that the configuration of the internal circuit is not limited to the above. The internal circuit may include an inductor instead of the capacitor 34 shown in FIG. 8, or the internal circuit may include both a capacitor and an inductor, for example. In other words, the internal circuit of the wiring sheet 30 may include a passive circuit including any element. Further, the internal circuit may include a switching circuit using a diode or the like instead of the relay circuit 334 shown in FIG. 9.

An element included in the internal circuit of the wiring sheet 30 may be formed using a Micro Electro Mechanical Systems (MEMS) process, for example. By using the MEMS process, an element which is reduced in size can be formed integrally with the wiring sheet 30.

As described above, various circuit configurations as shown in FIGS. 4 to 9 can be implemented in the electrical connection apparatus 1 by merely replacing the wiring sheet 30 of the electrical connection apparatus 1 shown in FIG. 1, for example. Therefore, a plurality of types of measurements can be performed on the object 2 to be inspected using the electrical connection apparatus 1. A DC test may be performed on the object 2 to be inspected by mounting, in the electrical connection apparatus 1, the wiring sheet 30 including the internal circuit for short-circuiting the first connection portions 31 and the second connection portions 32, for example. Further, a high-frequency test may be performed on the object 2 to be inspected by mounting, in the electrical connection apparatus 1, the wiring sheet 30 including the internal circuit having a matching circuit or a loopback circuit.

Further, by arranging the relay circuit 334 in the wiring sheet 30 shown in FIG. 9 of the electrical connection apparatus 1, the wiring length of an interposer circuit and a loopback circuit can be reduced compared to that when a relay element is arranged on the printed board 40. As a result, according to the electrical connection apparatus 1, it is possible to shorten a propagation path of an electrical signal and suppress the loss of an electrical signal and noise.

Further, by arranging the matching circuit 332 in the wiring sheet 30 shown in FIG. 5 of the electrical connection apparatus 1, wiring connected to the matching circuit 332 can be shortened. The matching circuit 332 can be arranged in the immediate vicinity of wiring for which impedance matching is to be performed, and therefore impedance matching can be performed effectively, for example.

In the measurement of the object 2 to be inspected, the stage 3 serves as a heat generation source. Therefore, an ambient temperature of a lower surface of the wiring board 20 facing the stage 3 is higher than that of other regions. Therefore, by arranging the wiring sheet 30 on an upper surface of the wiring board 20, an increase in an ambient temperature of an electronic component constituting the internal circuit of the wiring sheet 30 can be suppressed compared with that of an electronic component arranged on the lower surface of the wiring board 20. As a result, the electronic component functions at an ambient temperature that is equal to or less than an allowable temperature, and the measurement of the object 2 to be inspected can be accurately performed.

As described above, the electrical connection apparatus 1 according to an embodiment has the wiring sheet 30 including the internal circuit capable of constituting any circuit, which is interposed between the wiring board 20 and the printed board 40 in an attachable/detachable manner. Characteristics of the object 2 to be inspected can be measured with high accuracy with the electrical connection apparatus 1.

### Other Embodiments

Although an embodiment of the present invention has been described above, the discussion and drawings forming part of this disclosure should not be construed as limiting the invention. Various alternative embodiments, examples, and operational techniques will be apparent to those skilled in the art from this disclosure.

The wiring sheet 30 may include an internal circuit in which a plurality of types of circuit configurations are mixed, for example. The wiring sheet 30 may include an internal circuit in which the short-circuit wiring 331 and the matching circuit 332 are mixed, for example. Alternatively, the wiring sheet 30 may include an internal circuit in which an interposer circuit and a loopback circuit are mixed. The internal circuit may include the short-circuit wiring 331, the matching circuit 332, and the loopback wiring 333, or may further include the relay circuit 334, for example. Further, the loopback circuit may include the matching circuit 332. FIG. 10 shows an example of an internal circuit including the short-circuit wiring 331, the matching circuit 332, and the loopback wiring 333. In this way, any circuit can be configured in the internal circuit of the wiring sheet 30.

As described above, by mounting, in the electrical connection apparatus 1, the wiring sheet 30 including the internal circuit in which any circuit configurations are mixed, a plurality of types of measurements can be performed on the object 2 to be inspected with one wiring sheet 30.

FIG. 1 has shown a case where the electrical connection apparatus 1 in which the wiring sheet 30 is mounted includes the probes 10 in contact with signal terminals of the object 2 to be inspected. It is possible to measure electrical characteristics of an object 2 to be inspected not separated from a wafer or an object 2 to be inspected which is converted into a chip using the electrical connection apparatus 1 shown in FIG. 1, for example. Meanwhile, the wiring sheet 30 may be mounted in an electrical connection apparatus including a test socket, to support the measurement of electrical characteristics of the object 2 to be inspected performed in a state where the object 2 to be inspected is mounted in a package or the like. The test socket having a terminal for inspection, connected to an external terminal of the package in which the object 2 to be inspected is mounted, may be arranged on the wiring board 20 instead of the probes 10 of the electrical connection apparatus 1 shown in FIG. 1, for example.

Various circuit configurations shown in FIGS. 4 to 10 implemented in the electrical connection apparatus 1 can be implemented in the electrical connection apparatus including the test socket also by merely replacing the wiring sheet 30, for example. Further, it is possible to shorten wiring connected to the matching circuit 332 arranged in the wiring sheet 30 and shorten the wiring length of an interposer circuit and a loopback circuit constituted by the relay circuit 334 arranged in the wiring sheet 30. Therefore, in the electrical connection apparatus including the test socket also, characteristics of the object 2 to be inspected can be measured with high accuracy, as in the electrical connection apparatus 1 including the probes 10 described above.

In this way, it is needless to say that the present invention includes various embodiments not described above. Therefore, the technical scope of the present invention is defined only by matters specified in the invention that are within the scope of claims appropriate from the above description.

What is claimed is:

1. An electrical connection apparatus used for an inspection of an object to be inspected, the electrical connection apparatus comprising:
a plurality of terminals for inspection in contact with the object to be inspected;
a wiring board that includes a plurality of first electrodes each of which is connected to any one of the terminals for inspection, and a plurality of second electrodes each of which is electrically connected to any one of the first electrodes;
a wiring sheet that includes a first connection portion arranged on a first main surface, a second connection portion arranged on a second main surface facing the first main surface, and an internal circuit electrically connected to the first connection portion, and is laminated on the wiring board such that the first connection portion is connected to the second electrodes; and
a printed board that faces the wiring board with the wiring sheet therebetween and includes wiring patterns connected to the second connection portion;
wherein the wiring sheet is configured in an attachable/detachable manner between the wiring board and the printed board.

2. The electrical connection apparatus according to claim 1, wherein:
the wiring sheet is selected from among a plurality of wiring sheet candidates included in a wiring sheet group, each of which includes the first connection portion, the second connection portion, and the internal circuit;
each of the wiring sheet candidates included in the wiring sheet group includes an internal circuit having a configuration different from a configuration of another wiring sheet candidate of the wiring sheet candidates; and
the wiring sheet is configured in an attachable/detachable manner between the wiring board and the printed board in order to replace the wiring sheet laminated on the wiring board with another wiring sheet candidate of the wiring sheet candidates.

3. The electrical connection apparatus according to claim 1, wherein the wiring sheet has a structure in which a laminated body of a conductive film and an insulating film is interposed between cover films of an insulating material.

4. The electrical connection apparatus according to claim 1, wherein the internal circuit of the wiring sheet includes a circuit for electrically connecting the first connection portion and the second connection portion.

5. The electrical connection apparatus according to claim 4, wherein the internal circuit of the wiring sheet includes a circuit for short-circuiting the first connection portion and the second connection portion.

6. The electrical connection apparatus according to claim 4, wherein the internal circuit of the wiring sheet includes a matching circuit that has a first terminal connected to the first connection portion and a second terminal connected to the second connection portion and performs impedance matching between the first connection portion and the second connection portion.

7. The electrical connection apparatus according to claim 1, wherein the first connection portion is provided in plurality, and the internal circuit of the wiring sheet includes a circuit for electrically connecting any one of the first connection portions and the other one of the first connection portions.

8. The electrical connection apparatus according to claim 7, wherein the internal circuit of the wiring sheet includes a circuit for short-circuiting any one of the first connection portions and the other one of the first connection portions.

9. The electrical connection apparatus according to claim 7, wherein the internal circuit of the wiring sheet includes a capacitor connected in series between any one of the first connection portions and the other one of the first connection portions.

10. The electrical connection apparatus according to claim 1, wherein the first connection portion is provided in plurality, the second connection portion is provided in plurality, and the internal circuit of the wiring sheet includes a relay circuit that switches to electrically connect one of the first connection portions to either one of the second connection portions or the other one of the first connection portions.

11. The electrical connection apparatus according to claim 1, wherein the wiring board is a space transformer that extends a distance between the terminals for inspection to a distance between the wiring patterns in the printed board when viewed from a direction normal to a main surface of the wiring board.

12. The electrical connection apparatus according to claim 1, wherein each of the terminals for inspection is a probe having one end connected to any one of the first electrodes on the wiring board and the other end in contact with a signal terminal of the object to be inspected.

13. The electrical connection apparatus according to claim 1, wherein the terminals for inspection are disposed in a test socket connected to an external terminal of a package in which the object to be inspected is mounted.
